(19) United States
(12) Patent Application Publication
(10) Pub. No.: US 2026/0059682 A1
(43) Pub. Date: Feb. 26, 2026

(54) DISPLAY APPARATUS

(71) Applicant: LG Display Co., Ltd., Seoul (KR)

(72) Inventor: Juhan KIM, Paju-si (KR)

(73) Assignee: LG Display Co., Ltd., Seoul (KR)

(21) Appl. No.: 19/090,755

(22) Filed: Mar. 26, 2025

(30) Foreign Application Priority Data
Aug. 20, 2024 (KR) 10-2024-0111182

(51) Int. Cl. H05K 7/14; H05K 7/20; H10K 59/95

(52) U.S. Cl. CPC H05K 7/1417; H05K 7/20963; H10K 59/95

(57) ABSTRACT

A display apparatus can include a display panel, a flexible film connected to the display panel, a source printed circuit board connected to the flexible film, a connection member connected to the printed circuit board, a control printed circuit board connected to the connection member, and a guide holder that fixes the source printed circuit board and the control printed circuit board. The source printed circuit board and the control printed circuit board overlap each other under the display panel.

### CROSS-REFERENCE TO RELATED APPLICATION

The present application claims priority to Korean Patent Application No. 10-2024-0111182, filed Aug. 20, 2024 in the Republic of Korea, the entire contents of which is hereby expressly incorporated by reference into the present application.

### BACKGROUND OF THE DISCLOSURE

### Technical Field

The present disclosure relates to a display apparatus.

### Discussion of the Related Art

As the information society develops, various demands for display apparatuses for displaying images are increasing. Various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a high contrast ratio, and can be lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost. The OLED display apparatus can also be applied to display apparatuses mounted on vehicles.

The display apparatus can include a display panel for displaying a screen and a printed circuit board (PCB) for controlling the display panel. The PCB needs to be tightly connected to the display panel even in the event of an external impact and shaking.

### SUMMARY OF THE DISCLOSURE

The present disclosure is directed to providing a display apparatus in which a display panel and a printed circuit board are tightly connected.

The present disclosure is also directed to providing a display apparatus in which a printed circuit board can be easily mounted.

The present disclosure is also directed to providing a display apparatus in which it is possible to easily suppress, minimize or prevent a separation of a printed circuit board even in the event of external shaking and impact by tightly connecting the printed circuit board to a display panel.

The present disclosure is also directed to providing a display apparatus in which it is possible to easily suppress, minimize or prevent defects due to the separation of a printed circuit board even in the event of external shaking and impact.

Objects of the present disclosure are not limited to the above-described objects, and other technical objects can be inferred from the following embodiments of the present disclosure.

According to one or more embodiments of the present disclosure, there is provided a display apparatus including a display panel, a flexible film connected to the display panel, a source printed circuit board connected to the flexible film, a connection member connected to the printed circuit board, a control printed circuit board connected to the connection member, and a guide holder configured to fix the source printed circuit board and the control printed circuit board, wherein the source printed circuit board and the control printed circuit board overlap each other under the display panel.

According to another embodiment of the present disclosure, there is provided a display apparatus including a display panel, a heat dissipation sheet disposed under the display panel, a control printed circuit board connected to the display panel, and a guide holder disposed under the heat dissipation sheet, wherein the guide holder further includes a body portion, a first control hook disposed on the body portion, a base portion protruding from the body portion in a second direction, a protrusion protruding and extending from the base portion in the second direction, and a second control hook protruding from the protrusion in a thickness direction. The control printed circuit board is fixed on the body portion and the protrusion by the first control hook and the second control hook.

Detailed matters of other embodiments are included in the detailed description and accompanying drawings.

According to the embodiments of the present disclosure, the display panel and the printed circuit board can be tightly connected.

According to the embodiments of the present disclosure, the printed circuit board can be easily mounted.

According to the embodiments of the present disclosure, it is possible to easily suppress, minimize or prevent a separation of the printed circuit board even in the event of external shaking and impact by tightly connecting the printed circuit board to the display panel.

According to the embodiments of the present disclosure, it is possible to easily suppress, minimize or prevent defects due to the separation of the printed circuit board even in the event of external shaking and impact.

According to the embodiments of the present disclosure, defects of the printed circuit board can be suppressed to increase the life of the display apparatus, thereby reducing production energy.

However, effects obtainable from the present disclosure are not limited to the above-described effects, and other effects that are not mentioned will be able to be clearly understood by those skilled in the art to which the present disclosure pertains from the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is an enlarged view of area Q1 in FIG. 1.

FIG. 3 is a view illustrating a display panel of FIG. 2.

FIG. 4 is a side view of the display apparatus of FIG. 1.

FIG. 5 is a side view illustrating a bent state of a flexible film of FIG. 4.

FIG. 6 is a side view illustrating a bent state of a connection member of FIG. 5.

FIG. 7 is a perspective view of a guide holder of the display apparatus according to one embodiment of the present disclosure.

FIG. 8 is a plan view illustrating a printed circuit board fixed to the guide holder according to one embodiment of the present disclosure.

FIG. 9 is a plan view illustrating a source printed circuit board and a control printed circuit board that are fixed to the guide holder according to one embodiment of the present disclosure.

FIG. 10 is an enlarged view of area Q2 in FIG. 9.

FIG. 11 is a cross-sectional view along line D-D′ in FIG. 10.

FIG. 12 is a cross-sectional view of a display area in the display panel according to one embodiment of the present disclosure.

FIG. 13 is a cross-sectional view of a touch part of FIG. 12 taken at a different angle.

FIG. 14 is a cross-sectional view along line A-A′ in FIG. 1.

FIG. 15 is a cross-sectional view along line B-B′ in FIG. 3.

FIG. 16 is a cross-sectional view along line C-C′ in FIG. 3.

FIG. 17 is a plan view of a display apparatus according to another embodiment of the present disclosure.

FIG. 18 is an enlarged view of area Q3 in FIG. 17.

FIG. 19 is a cross-sectional view along line E-E′ in FIG. 18.

FIG. 20 is a plan view of the display apparatus according to another embodiment of the present disclosure.

FIG. 21 is a cross-sectional view along line F-F′ in FIG. 20.

### DETAILED DESCRIPTION OF THE EMBODIMENTS

Hereinafter, various embodiments of the present disclosure will be described with reference to the accompanying drawings. In the specification, when a first component (or an area, a layer, a portion, etc.) is described as “on,” “connected,” or “coupled to” a second component, it means that the first component can be directly connected/coupled to the second component or a third component can be disposed therebetween. Further, the term “can” fully encompasses all the meanings and coverages of the term “may” and vice versa.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as “first” and “second” can be used to describe various components, but the components are not limited by the terms. The terms are used only for the purpose of distinguishing one component from another and may not define order or sequence. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance.

Now the embodiments of the present disclosure will be discussed referring to the figures. All the components of each display apparatus according to all embodiments of the present disclosure are operatively coupled and configured.

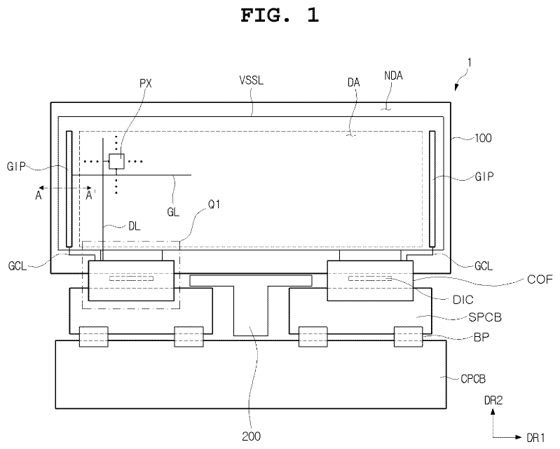

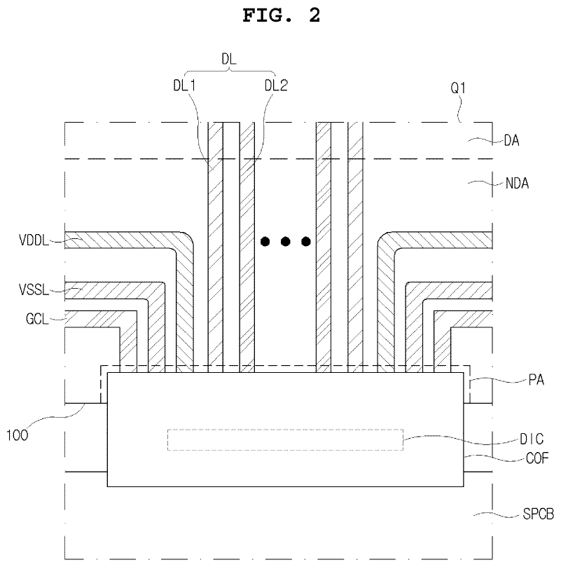

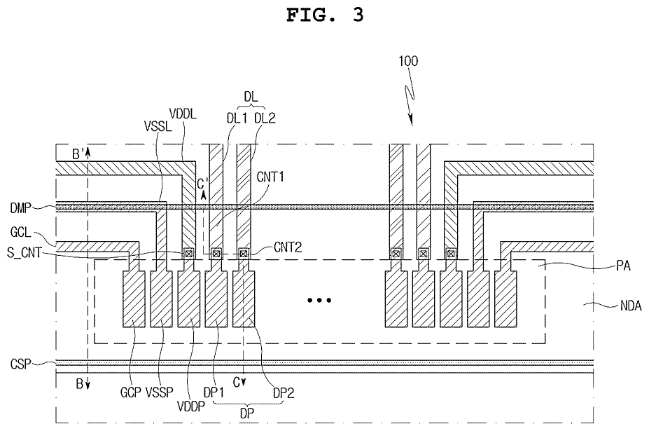

FIG. 1 is a plan view of a display apparatus according to one or more embodiments of the present disclosure. FIG. 2 is an enlarged view of area Q1 in FIG. 1. FIG. 3 is a view illustrating only a display panel of FIG. 2.

FIG. 3 is a view of FIG. 2 from which a flexible film COF, a source printed circuit board SPCB, and a drive IC DIC are omitted except for a display panel 100. In FIG. 3, for convenience of description, ratios between components are adjusted.

Referring to FIGS. 1 to 3, a display apparatus 1 can be an apparatus including both a display function for displaying a video and a touch sensing function for sensing touch of a user, but is not limited thereto. For example, the display apparatus 1 can include only one of the display function for displaying a video and the touch sensing function for sensing touch of a user.

The display apparatus 1 can be an electroluminescent display apparatus or a micro light-emitting diode display apparatus that includes a touch sensor. The electroluminescent display apparatus including the touch sensor can be an organic light-emitting diode (OLED) display apparatus, a quantum-dot light-emitting diode display apparatus, or an inorganic light-emitting diode display apparatus.

The display apparatus 1 according to the present embodiment can be a vehicle display apparatus, but is not limited thereto. For example, the description of the display apparatus 1 can be applied without limitation to the type of the apparatus as long as a display apparatus is an apparatus including a display function.

When the display apparatus 1 according to the present embodiment is a vehicle display apparatus, the display apparatus 1 can include a function of manipulating at least some of various functions of a vehicle, a function of displaying various pieces of information about the vehicle, etc.

When the display apparatus 1 according to the present embodiment is a vehicle display apparatus, the display apparatus 1 can be disposed on a dashboard of a vehicle. The display apparatus 1 can be disposed across a driver's seat and a passenger's seat that are disposed at front seats of a vehicle, but is not limited thereto.

Both a driver in the driver's seat and a co-driver in the passenger's seat can use the display apparatus 1. The display apparatus 1 can provide different videos to each of the driver in the driver's seat and the co-driver in the passenger's seat. However, the embodiments of the present disclosure are not limited thereto, and the display apparatus 1 can provide the same video to both the driver in the driver's seat and the co-driver in the passenger's seat.

The display apparatus 1 can include a display panel 100. The display panel 100 can include a display area DA and a non-display area NDA.

The display area DA can be an area in which light is emitted to the outside to display a screen. The display area DA can further include a function of sensing touch of a user. In this case, the display area DA can correspond to a touch sensing area, but is not limited thereto.

The display area DA can correspond to the shape of the display panel 100, but is not limited thereto.

The display panel 100 can include a plurality of pixels PX. The plurality of pixels PX can be disposed in the display area DA. The plurality of pixels PX can be repeatedly disposed in a first direction DR1 and a second direction DR2.

The non-display area NDA can be an area in which light is not emitted to the outside so as not to display a screen. The non-display area NDA can be located around the display area DA. The non-display area NDA can surround the display area DA, but the embodiments of the present disclosure are not limited thereto. The non-display area NDA can surround the display area DA entirely or only in part(s). A bezel area of the display apparatus 1 can be defined by the non-display area NDA, but the embodiments of the present disclosure are not limited thereto.

The display panel 100 can be a rigid display panel, but is not limited thereto. The display panel 100 can be a flexible display panel of which shape can be deformed, such as a foldable, bendable, rollable, or stretchable display panel.

The display panel 100 can include a long side and a short side that form an edge of the display panel 100. The long side can extend in the first direction DR1, and the short side can extend in the second direction DR2.

The first direction DR1 and the second direction DR2 can be directions intersecting each other. The first direction DR1 and the second direction DR2 can be orthogonal, but are not limited thereto. The first direction DR1 and the second direction DR2 are provided to clarify the description of the invention, the first direction DR1 and the second direction DR2 are relative, and the embodiments of the present disclosure are not limited thereto.

The display apparatus 1 can further include a gate driving unit GIP, a source printed circuit board SPCB, a flexible film COF, a drive IC DIC, a control printed circuit board CPCB, a connection member BP, a gate line GL, a gate control line GCL, a data line DL, a low-potential voltage line VSSL, and a high-potential voltage line VDDL.

A pad area PA can overlap the flexible film COF. The pad area PA can be attached to the flexible film COF. For example, the display panel 100 and the flexible film COF can be attached through the pad area PA.

The pad area PA can be disposed in the non-display area NDA. The pad area PA can include a plurality of pads. The pad area PA can include a gate control pad GCP, a low-potential voltage pad VSSP, a high-potential voltage pad VDDP, a first data pad DP1, and a second data pad DP2. The gate control pad GCP, the low-potential voltage pad VSSP, the high-potential voltage pad VDDP, the first data pad DP1, and the second data pad DP2 can be disposed in the pad area PA.

The pad area PA can be provided as a plurality of pad areas. When the pad area PA is provided as a plurality of pad areas, the gate control pad GCP can be omitted from some pad areas PA. For example, the plurality of pad areas PA can be repeatedly disposed in the first direction DR1, and the gate control pad GCP can be omitted from the remaining pad areas PA excluding the pad areas PA disposed at both ends in the first direction DR1.

The gate driving unit GIP can be disposed in the non-display area NDA. The gate driving unit GIP can be disposed at at least one of one side and the other side of the display area DA in the first direction DR1, but is not limited thereto. In a plan view, the gate driving unit GIP can be disposed at the left side and the other side of the display area DA.

The gate driving unit GIP can include a plurality of transistors. Transistors disposed in the gate driving unit GIP can be connected to the pixels PX through the gate lines GLs. The gate driving unit GIP can apply a gate signal to each pixel PX through the gate line GL.

The gate driving unit GIP can receive a gate control signal from the drive IC DIC through the gate control line GCL. The gate driving unit GIP can generate a scan signal and a light-emitting signal (or a light-emitting control signal) based on the gate control signal.

The gate driving unit GIP can include a scan driver and a light-emitting signal driver. The scan driver can generate a scan signal in a row-sequential manner and supply the scan signal to the scan lines in order to drive one or more scan lines connected to each pixel PX row. The light-emitting signal driver can generate a light-emitting signal in a row-sequential manner and supply the light-emitting signal to light-emitting signal lines in order to drive one or more light-emitting signal lines connected to each pixel PX row.

The source printed circuit board SPCB can be connected to the display panel 100 through the flexible film COF. The source printed circuit board SPCB can be electrically connected to the pixel PX of the display area DA through the flexible film COF. The source printed circuit board SPCB can be electrically connected to the flexible film COF. The source printed circuit board SPCB and the flexible film COF can be electrically connected through the plurality of pads VSSP, VDDP, and DP.

The source printed circuit board SPCB can have various types of components disposed to supply various signals, such as a gate control signal, a driving signal, a data signal, etc., to the drive IC DIC. The source printed circuit board SPCB can be a PCB, but is not limited thereto.

The source printed circuit board SPCB can be connected to the display panel 100 through the flexible film COF in the non-display area NDA. The source printed circuit board SPCB can be provided as a plurality of source printed circuit boards along the non-display area NDA, but is not limited thereto. The number of source printed circuit boards SPCBs can vary according to a design.

The flexible film COF can be connected to the display panel 100 and the source printed circuit board SPCB. The flexible film COF can be attached to each of the display panel 100 and the source printed circuit board SPCB and electrically connected to each of the display panel 100 and the source printed circuit board SPCB. For example, the display panel 100 and the source printed circuit board SPCB can be electrically connected through the flexible film COF. The flexible film COF can be provided as a plurality of flexible films, but is not limited thereto.

The flexible film COF can be attached to the display panel 100 in the non-display area NDA. The flexible film COF can be repeatedly disposed along the non-display area NDA.

A single source printed circuit board SPCB can be electrically connected to the display panel 100 through at least one flexible film COF. A plurality of source printed circuit boards SPCBs disposed along the non-display area NDA can be electrically connected to the display panel 100 through one flexible film COF, but are not limited thereto. For example, the source printed circuit board SPCB can be electrically connected to the display panel 100 through two or more flexible films COFs.

The flexible film COF can be electrically connected to the pad area PA. Accordingly, the flexible film COF can supply gate control signals, driving signals, power voltages, data voltages, etc. to the plurality of pixels PX and the gate driving unit GIP that are disposed in the display area DA.

The flexible film COF can be a flexible insulating film. The flexible film COF can include, for example, polycarbonate, polyethylene terephthalate, polyimide, polyamide, polyester, polyacrylate, polymethyl methacrylate, etc., but is not limited thereto.

The drive IC DIC can be mounted on the flexible film COF. The drive IC DIC can be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC can drive the display apparatus 1. The drive IC DIC can process data signals for displaying a video, various driving signals for processing the data signals, etc. The drive IC DIC can include a gate driver IC, a data driver IC, etc.

The control printed circuit board CPCB can be connected to the source printed circuit board SPCB through the connection member BP. The control printed circuit board CPCB can be electrically connected to the source printed circuit board SPCB through the connection member BP. The control printed circuit board CPCB can be electrically connected to the connection member BP.

The control printed circuit board CPCB can be provided with a controller for controlling the operation of a data driving circuit, a gate driving circuit, etc., and a power management integrated circuit (PMIC) for supplying various types of voltages or currents to or controlling various types of voltages or currents, which will be supplied to the display panel 100, the data driving circuit, the gate driving circuit, etc.

The control printed circuit board CPCB can be a PCB, but is not limited thereto.

The connection member BP can be connected to the source printed circuit board SPCB and the control printed circuit board CPCB. The connection member BP can be attached to each of the source printed circuit board SPCB and the control printed circuit board CPCB and electrically connected to each of the source printed circuit board SPCB and the control printed circuit board CPCB.

For example, the source printed circuit board SPCB and the control printed circuit board CPCB can be electrically connected through the connection member BP.

One control printed circuit board CPCB can be electrically connected to the source printed circuit board SPCB through at least one connection member BP. A plurality of control printed circuit boards CPCBs disposed along the non-display area NDA can be electrically connected to the source printed circuit board SPCB through a single connection member BP, but are not limited thereto. For example, the control printed circuit board CPCB can be electrically connected to the source printed circuit board SPCB through two or more connection members BPs.

The connection member BP can be a flexible insulating film. The connection member BP can be a flexible printed circuit (FPC), a flexible flat cable (FFC), etc., but is not limited thereto.

The source printed circuit board SPCB and the control printed circuit board CPCB are configured separately, but are not limited thereto. For example, at least one source printed circuit board SPCB and the control printed circuit board CPCB can be implemented by being integrated into a single printed circuit board.

The gate line GL can be extended from the gate driving unit GIP and connected to the pixel PX. The gate line GL can electrically connect the gate driving unit GIP and the pixel PX. The gate line GL can apply the gate signal from the gate driving unit GIP to each pixel PX.

The gate control line GCL can be disposed in the non-display area NDA. The gate control line GCL can extend from the pad area PA to the gate driving unit GIP and can be electrically connected to the gate driving unit GIP.

The gate control line GCL can apply the gate control signal to the gate driving unit GIP. The gate control signal can be transmitted from the control printed circuit board CPCB, the source printed circuit board SPCB, or the drive IC DIC. The gate control line GCL can electrically connect the gate driving unit GIP to the control printed circuit board CPCB, the source printed circuit board SPCB, or the drive IC DIC.

The gate control line GCL can be connected to the pad area PA. The gate control line GCL can be physically connected to the gate control pad GCP and electrically connected to the gate control pad GCP. The gate control line GCL and the gate control pad GCP can be formed integrally, but are not limited thereto.

The gate control pad GCP can be disposed at an outermost side of the pad area PA, but is not limited thereto.

The data line DL can extend from the pad area PA and can be connected to the pixel PX of the display area DA. The data line DL can apply the data signal to each pixel PX. The data signal can be applied from the control printed circuit board CPCB, the source printed circuit board SPCB, or the drive IC DIC. The data line DL can electrically connect the pixel PX to the control printed circuit board CPCB, the source printed circuit board SPCB, or the drive IC DIC.

The data line DL can include a first data line DL1 and a second data line DL2. The data line DL can be connected to the data pads DP1 and DP2. The first data line DL1 can be electrically connected in contact with the first data pad DP1 through a first data contact hole CNT1. The second data line DL2 can be electrically connected in contact with the second data pad DP2 through a second data contact hole CNT2.

The low-potential voltage line VSSL can be disposed in the non-display area NDA to surround the display area DA. The low-potential voltage line VSSL can be disposed in the non-display area NDA with the display area DA and the gate driving unit GIP interposed therebetween. For example, the gate driving unit GIP can be disposed between the display area DA and the low-potential voltage line VSSL.

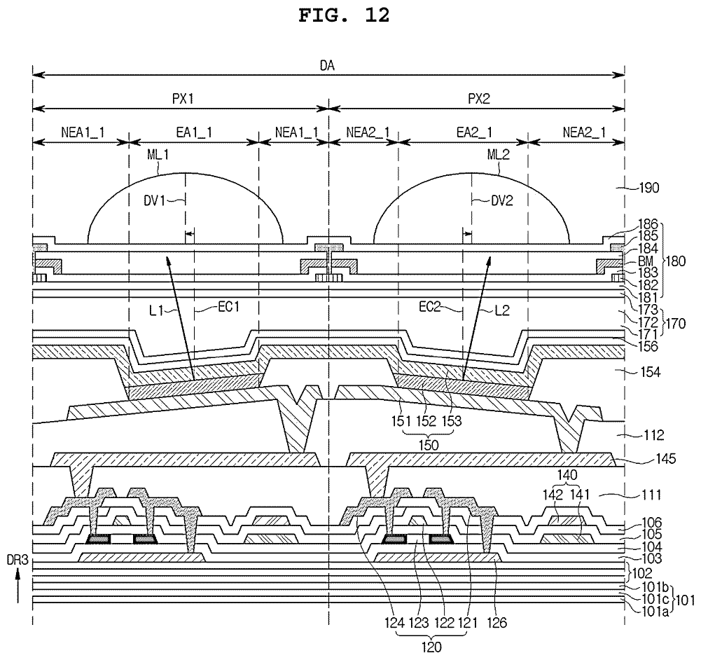

The low-potential voltage line VSSL can apply a low-potential voltage to the pixel PX. The low-potential voltage line VSSL can be electrically connected to the cathode electrode 153 (see FIG. 12) of the pixel PX to apply a low-potential voltage.

The low-potential voltage line VSSL can be connected to the pad area PA. The low-potential voltage line VSSL can be physically connected to the low-potential voltage pad VSSP and electrically connected to the low-potential voltage pad VSSP. The low-potential voltage line VSSL and the low-potential voltage pad VSSP can be formed integrally, but are not limited thereto.

The high-potential voltage line VDDL can be disposed between the display area DA and the low-potential voltage line VSSL. The high-potential voltage line VDDL can apply a high-potential voltage to the pixel PX. The high-potential voltage line VDDL can be electrically connected to the anode electrode 151 (see FIG. 12) of the pixel PX to apply a high-potential voltage.

The high-potential voltage line VDDL can be connected to the pad area PA. The high-potential voltage line VDDL can be physically connected to the high-potential voltage pad VDDP and electrically connected to the high-potential voltage pad VDDP. The high-potential voltage line VDDL can come into contact with the high-potential voltage pad VDDP by a high-potential contact hole S CNT.

However, the embodiments of the present disclosure are not limited thereto, and the high-potential voltage line VDDL and the high-potential voltage pad VDDP can be formed integrally. For example, the high-potential voltage line VDDL can be formed of the same material and the same conductive layer as the high-potential voltage pad VDDP, and the high-potential voltage line VDDL and the high-potential voltage pad VDDP are formed together by the same mask process.

The display apparatus 1 can further include a dam part DMP. The dam part DMP can be disposed in the non-display area NDA. The dam part DMP can be disposed to surround the display area DA, but is not limited thereto. The dam part DMP can be disposed to overlap at least a part of the low-potential voltage line VSSL. The dam part DMP can be disposed between the display area DA and the pad area PA in the non-display area NDA.

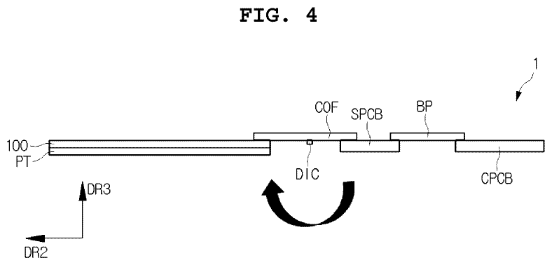

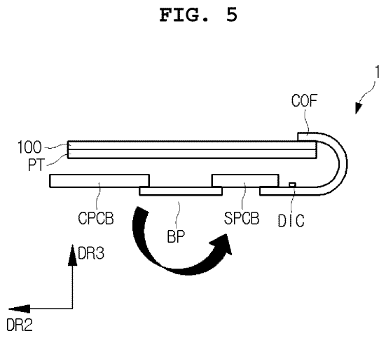

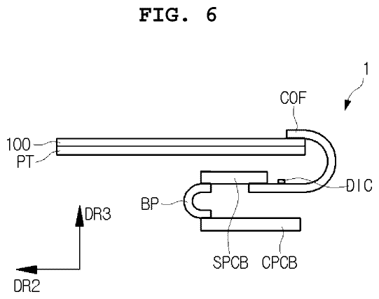

FIG. 4 is a side view of the display apparatus of FIG. 1. FIG. 5 is a side view illustrating a bent state of a flexible film of FIG. 4. FIG. 6 is a side view illustrating a bent state of a connection member of FIG. 5.

Particularly, FIGS. 4 to 6 illustrate a process and method of mounting the source printed circuit board SPCB and the control printed circuit board CPCB below the display panel 100.

Referring to FIG. 4, the display apparatus 1 can further include a heat dissipation sheet PT. The heat dissipation sheet PT can be disposed on the display panel 100. The heat dissipation sheet PT can be disposed under the display panel 100.

The heat dissipation sheet PT can be formed of a material with high thermal conductivity, such as a metal. The embodiments of the present disclosure are not limited thereto, but, for example, the heat dissipation sheet PT can include a metal with excellent thermal conductivity, such as aluminum or an aluminum alloy. The heat dissipation sheet PT can discharge heat generated during the driving of the display panel 100 to the outside, thereby decreasing a temperature of the display apparatus 1.

In addition, the heat dissipation sheet PT can be formed of a material with high strength, thereby securing the rear rigidity of the display apparatus 1 and protecting the display apparatus 1 from an external impact.

The embodiments of the present disclosure are not limited thereto, but a plate that can increase the strength and/or rigidity of the display panel 100 can be further disposed between the heat dissipation sheet PT and the display panel 100. In addition, the plate can prevent static electricity generation etc. through surface electrification treatment.

A cover glass can be further disposed on the display panel 100. The cover glass can serve to protect the display panel 100 thereunder. When the cover glass is disposed, the display panel 100 can be disposed between the cover glass and the heat dissipation sheet PT.

Referring further to FIG. 5, the flexible film COF can be bent in a thickness direction (a third direction DR3). Accordingly, the flexible film COF can have one side attached to an upper portion of the display panel 100 and the other side moved to a lower portion of the display panel 100, and the drive IC DIC can also be moved to the lower portion of the display panel 100.

By bending the flexible film COF, a part of the flexible film COF and the drive IC DIC can be disposed on the lower portion of the display panel 100. The heat dissipation sheet PT can be disposed between the part of the flexible film COF, the drive IC DIC, and the display panel 100.

Referring further to FIG. 6, the connection member BP can be bent in the thickness direction (the third direction DR3). Accordingly, the connection member BP can have one side fixedly attached to an upper portion of the source printed circuit board SPCB and the other side moved to a lower portion of the source printed circuit board SPCB, and the control printed circuit board CPCB can also be moved to the lower portion of the source printed circuit board SPCB.

The source printed circuit board SPCB can be disposed between the control printed circuit board CPCB and the display panel 100.

The source printed circuit board SPCB can overlap the control printed circuit board CPCB in the thickness direction (the third direction DR3). The source printed circuit board SPCB and the control printed circuit board CPCB can overlap the display panel 100 in the thickness direction (the third direction DR3). The source printed circuit board SPCB and the control printed circuit board CPCB can overlap the heat dissipation sheet PT in the thickness direction (the third direction DR3).

All areas of the source printed circuit board SPCB and the control printed circuit board CPCB can overlap the display panel 100 in the thickness direction (the third direction DR3), but the embodiments of the present disclosure are not limited thereto.

By bending the flexible film COF and the connection member BP, the source printed circuit board SPCB and the control printed circuit board CPCB can be mounted more easily.

Even when the sizes of the source printed circuit board SPCB and the control printed circuit board CPCB are large, the source printed circuit board SPCB and the control printed circuit board CPCB can be disposed to overlap each other to reduce areas of the source printed circuit board SPCB and the control printed circuit board CPCB, thereby more easily mounting the source printed circuit board SPCB and the control printed circuit board CPCB.

A guide holder 200 can fix the source printed circuit board SPCB and the control printed circuit board CPCB. In FIG. 1, the guide holder 200 is illustrated as being disposed outside the display panel 100, but the guide holder 200 can be disposed below the display panel 100 by bending the flexible film COF.

The guide holder 200 can be disposed under the heat dissipation sheet PT. The guide holder 200 can be fixedly attached to a lower surface of the heat dissipation sheet PT, but is not limited thereto, and the guide holder 200 can be spaced a predetermined distance from the heat dissipation sheet PT, and a location of the guide holder 200 can be fixed by another component.

As the guide holder 200 fixes the source printed circuit board SPCB and the control printed circuit board CPCB, connection between the display panel 100, the source printed circuit board SPCB, and the control printed circuit board CPCB can be solidified. For example, even when external shaking and impact are transferred to the display apparatus 1, the fixation of the source printed circuit board SPCB and the control printed circuit board CPCB can be maintained.

Accordingly, the flexible film COF can be tightly attached to the display panel 100 and the source printed circuit board SPCB, and the connection member BP can be tightly attached to the source printed circuit board SPCB and the control printed circuit board CPCB.

Accordingly, even when external impact and/or shaking are transferred to the display apparatus 1, the connection between the source printed circuit board SPCB, the control printed circuit board CPCB, and the display panel 100 can be tightly maintained. By suppressing or preventing separation of at least one of the source printed circuit board SPCB and the control printed circuit board CPCB, it is possible to suppress, minimize or prevent defects due to the separation of the source printed circuit board SPCB and the control printed circuit board CPCB. Furthermore, by suppressing, minimizing or preventing defects that can occur, it is possible to increase the life of the display apparatus 1 and reduce production energy.

Hereinafter, the guide holder 200 and coupling of the guide holder 200 with the source printed circuit board SPCB and the control printed circuit board CPCB will be described in detail.

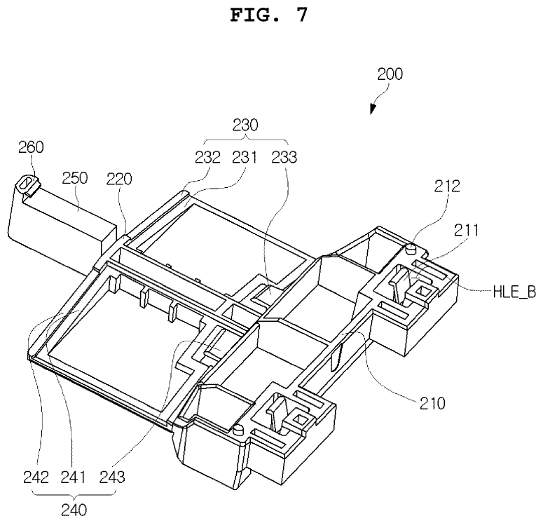

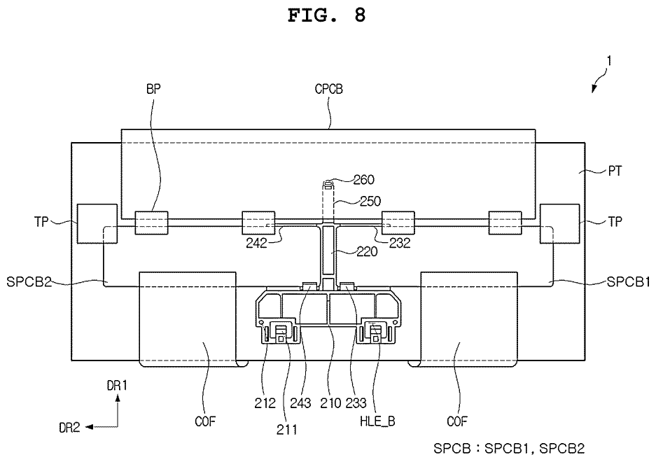

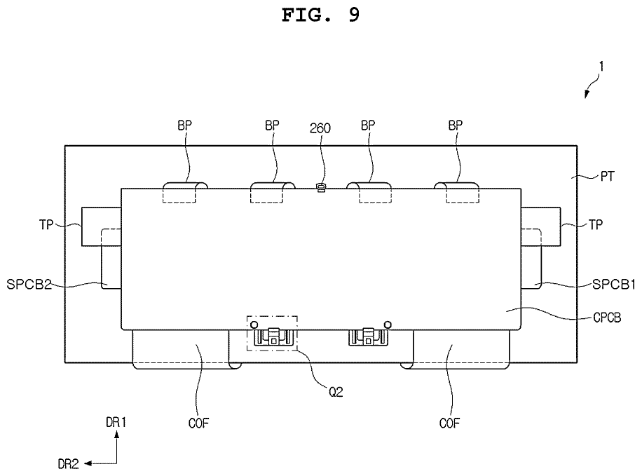

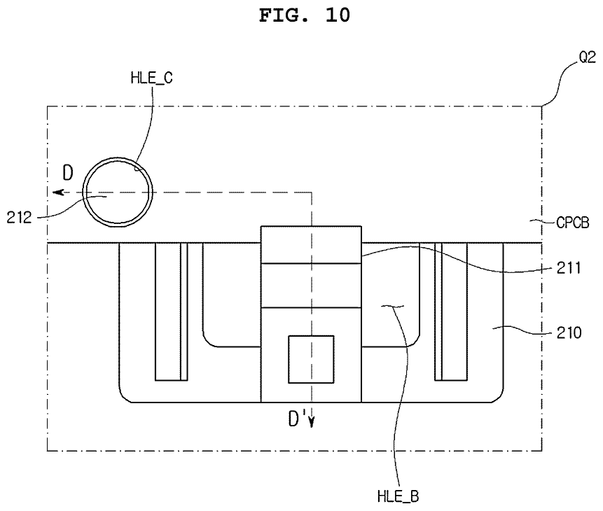

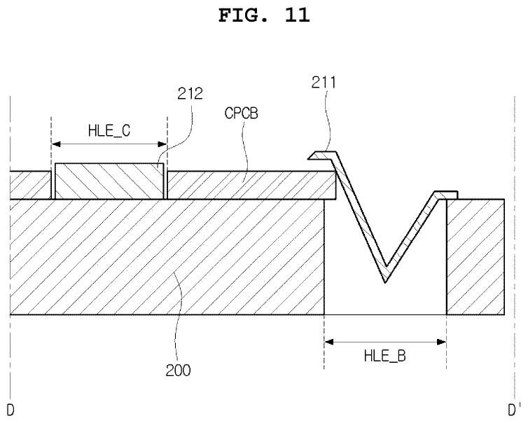

FIG. 7 is a perspective view of a guide holder of the display apparatus according to one embodiment of the present disclosure. FIG. 8 is a plan view illustrating a printed circuit board fixed to the guide holder according to one embodiment of the present disclosure. FIG. 9 is a plan view illustrating a source printed circuit board and a control printed circuit board that are fixed to the guide holder according to one embodiment of the present disclosure. FIG. 10 is an enlarged view of area Q2 in FIG. 9. FIG. 11 is a cross-sectional view along line D-D′ in FIG. 10.

Particularly, FIGS. 8 and 9 illustrate plan views of a back surface (a rear surface) of the display apparatus 1 in which the flexible film COF is bent.

More specifically, FIG. 8 illustrates the fixation coupling of the guide holder 200 and the source printed circuit board SPCB in a bent state of the flexible film COF as illustrated in FIG. 5. FIG. 9 illustrates the fixation coupling of the guide holder 200, the source printed circuit board SPCB, and the control printed circuit board CPCB in bent states of the flexible film COF and the connection member BP as illustrated in FIG. 6.

Referring to FIGS. 7 to 11, the guide holder 200 can include a body portion 210, a first control hook 211 disposed on the body portion 210, a body protrusion 212 disposed on the body portion 210, a base portion 220 protruding from the body portion 210 in the second direction DR2, a first source fixing member 230 extending from the base portion 220 to the other side in the first direction DR1, a second source fixing member 240 extending from the base portion 220 to one side in the first direction DR1, a protrusion 250 protruding from the base portion 220 in the second direction DR2, and a second control hook 260 protruding from the protrusion 250 in the thickness direction (the third direction DR3).

The source printed circuit board SPCB and the control printed circuit board CPCB can be seated on one surface of the guide holder 200.

An adhesive member and/or a friction member can be further disposed on the other surface of the guide holder 200. The other surface of the guide holder 200 can refer to a surface facing the heat dissipation sheet PT. An adhesive member and/or a friction member can be further disposed between the guide holder 200 and the heat dissipation sheet PT, thereby fixing the guide holder 200 more easily and more tightly.

The body portion 210 can provide a space in which the control printed circuit board CPCB can be seated. The control printed circuit board CPCB can be seated on one surface of the body portion 210.

The body portion 210 can define a body hole HLE_B passing therethrough in the thickness direction (the third direction DR3). However, the embodiments of the present disclosure are not limited thereto, and the body hole HLE_B can be omitted.

The first control hook 211 can fix the control printed circuit board CPCB along with the second control hook 260 and the body protrusion 212. The first control hook 211 can include a hook, and the hook can overlap the control printed circuit board CPCB in the thickness direction (the third direction DR3).

The first control hook 211 can control the movement of the control printed circuit board CPCB in the second direction DR2 and the movement of the control printed circuit board CPCB in the thickness direction (the third direction DR3) through the hook.

The first control hook 211 can be disposed on the body portion 210. The first control hook 211 can be connected to the body portion 210. The first control hook 211 can be disposed on the one surface of the body portion 210. When the body portion 210 includes the body hole HLE_B, at least a part of the first control hook 211 can be disposed inside the body hole HLE_B. However, the embodiments of the present disclosure are not limited thereto, and the first control hook 211 can be connected to an inner wall of the body hole HLE_B.

At least a part of the first control hook 211 can have elasticity. The first control hook 211 can have elasticity by including an elastic material or can be formed so that at least a part of a connection area connected to the body portion 210 has elasticity. The embodiments of the present disclosure are not limited thereto, but, for example, the first control hook 211 can be formed in the shape that has at least one bent portion so that the first control hook 211 can have elasticity.

As the first control hook 211 has elasticity, the control printed circuit board CPCB can be more easily inserted between the first control hook 211 and the second control hook 260, and the control printed circuit board CPCB can be more easily fixed by the elasticity.

The first control hook 211 can be provided as a plurality of first control hooks. For example, the first control hook 211 connected to the body portion 210 can be provided as two first control hooks. The first control hook 211 can be disposed at one side and the other side of the body portion 210 in the first direction DR1. Accordingly, the control printed circuit board CPCB can be fixed more easily.

The body protrusion 212 can be disposed on the body portion 210. The body protrusion 212 can protrude from the body portion 210 in the thickness direction (the third direction DR3).

The control printed circuit board CPCB can define a substrate hole HLE_C passing therethrough in the thickness direction (the third direction DR3). A location of the substrate hole HLE_C can correspond to a location of the body protrusion 212.

The body protrusion 212 can be inserted into the substrate hole HLE_C defined in the control printed circuit board CPCB. Accordingly, the movement of the control printed circuit board CPCB in the first direction DR1 and the second direction DR2 can be controlled. As the body protrusion 212 is inserted into the substrate hole HLE_C, the control printed circuit board CPCB can be more easily fixed.

The base portion 220 can protrude from the body portion 210 in the second direction DR2. The base portion 220 and the body portion 210 can have a step. One surface of the base portion 220 and one surface of the body portion 210 can have different heights. Here, the one surface of the base portion 220 can refer to a surface on which the source printed circuit board SPCB is seated, and the one surface of the body portion 210 can refer to a surface on which the control printed circuit board CPCB is seated.

The base portion 220 can connect the protrusion 250 to the body portion 210 and fix the first source fixing member 230 and the second source fixing member 240.

Each of the first source fixing member 230 and the second source fixing member 240 can fix the source printed circuit board SPCB. The source printed circuit board SPCB can be provided as a plurality of source printed circuit boards, and the plurality of source printed circuit boards SPCBs can be fixedly disposed on the first source fixing member 230 and the second source fixing member 240, respectively. For example, a first source printed circuit board SPCB1 can be fixed by the first source fixing member 230, and a second source printed circuit board SPCB2 can be fixed by the second source fixing member 240.

The first source fixing member 230 can extend from the base portion 220 to the other side in the first direction DR1. The first source fixing member 230 can include a first source seating portion 231, a first partition 232, and a first source hook 233.

The first source seating portion 231 can extend from the base portion 220 to the other side in the first direction DR1 to provide a space in which the first source printed circuit board SPCB1 can be seated. The first source seating portion 231 and the body portion 210 can have a step. The one surface of the first source seating portion 231 and the one surface of the body portion 210 can have different heights. Here, the one surface of the first source seating portion 231 can refer to a surface on which the first source printed circuit board SPCB1 is seated, and the one surface of the body portion 210 can refer to a surface on which the control printed circuit board CPCB is seated.

Since the first source seating portion 231 and the body portion 210 have a step, the first source printed circuit board SPCB1 and the control printed circuit board CPCB can overlap each other, the first source printed circuit board SPCB1 can be seated on the first source seating portion 231, and the control printed circuit board CPCB can be seated on the body portion 210.

The embodiments of the present disclosure are not limited thereto, but a friction member can be further disposed on the one surface of the first source seating portion 231. Accordingly, the first source printed circuit board SPCB1 can be more tightly fixed on the one surface of the first source seating portion 231.

The first partition 232 can be curved from the first source seating portion 231 and can protrude in the thickness direction (the third direction DR3). The first partition 232 can control the movement of the first source printed circuit board SPCB1 in the second direction DR2 along with the body portion 210. The first source printed circuit board SPCB1 can be disposed on the first source seating portion 231 and fixedly disposed between the first partition 232 and the body portion 210.

The first source hook 233 can protrude from the body portion 210 in the second direction DR2. The first source hook 233 can protrude from the body portion 210 toward the first source seating portion 231. The first source hook 233 can have a different height from the first source seating portion 231.

In the thickness direction (the third direction DR3), the first source printed circuit board SPCB1 can be disposed between the first source seating portion 231 and the first source hook 233. The first source printed circuit board SPCB1 can overlap the first source hook 233 in the thickness direction (the third direction DR3).

Through the first source hook 233, the movement of the first source printed circuit board SPCB1 in the thickness direction (the third direction DR3) can be fixed.

The above description of the first source fixing member 230 and the first source printed circuit board SPCB1 can be applied to the second source fixing member 240 and the second source printed circuit board SPCB2 in substantially the same manner. Accordingly, overlapping description of the second source fixing member 240 and the second source printed circuit board SPCB2 will be omitted or simplified.

The second source fixing member 240 can extend from the base portion 220 to one side in the first direction DR1. The second source fixing member 240 can include a second source seating portion 241, a second partition 242, and a second source hook 243.

The second source printed circuit board SPCB2 can be seated on the second source seating portion 241. The second source printed circuit board SPCB2 can be disposed between the second partition 242 and the body portion 210, thereby restricting the movement in the second direction DR2. In the thickness direction (the third direction DR3), the second source printed circuit board SPCB2 can be disposed between the second source seating portion 241 and the second source hook 243, thereby restricting the movement in the thickness direction (the third direction DR3).

The display apparatus 1 can further include an adhesive tape TP. The adhesive tape TP can attach the source printed circuit board SPCB onto the heat dissipation sheet PT. For example, by the adhesive tape TP, the source printed circuit board SPCB can be attached onto the heat dissipation sheet PT and fixed more tightly.

The protrusion 250 can protrude from the base portion 220 in the second direction DR2. The protrusion 250 can provide a space in which the control printed circuit board CPCB can be seated. The control printed circuit board CPCB can be placed on one surface of the protrusion 250. The one surface of the protrusion 250 can have a step from the one surface of the first source seating portion 231 and one surface of the second source seating portion 241.

The control printed circuit board CPCB can be seated on the one surface of the body portion 210 and the one surface of the protrusion 250.

The second control hook 260 can protrude from the protrusion 250 in the thickness direction (the third direction DR3) and have a hook shape. The second control hook 260 can be disposed at one side of the control printed circuit board CPCB in the second direction DR2, thereby restricting the movement of the control printed circuit board CPCB in the second direction DR2. Since the second control hook 260 includes a hook shape, the second control hook 260 can overlap the control printed circuit board CPCB in the thickness direction (the third direction DR3) and restrict the movement of the control printed circuit board CPCB in the thickness direction (the third direction DR3).

The embodiments of the present disclosure are not limited thereto, but the second control hook 260 can have elasticity like the first control hook 211. Accordingly, the control printed circuit board CPCB can be more easily inserted and more tightly fixed.

The control printed circuit board CPCB can be fixedly disposed between the first control hook 211 and the second control hook 260.

Since the source printed circuit board SPCB and the control printed circuit board CPCB are fixed by the guide holder 200, even when external shaking and impact are transferred, connection with the display panel 100 can be solid, thereby suppressing or preventing defects due to separation of the source printed circuit board SPCB and the control printed circuit board CPCB.

Hereinafter, a cross-sectional structure of the display panel 100 will be described.

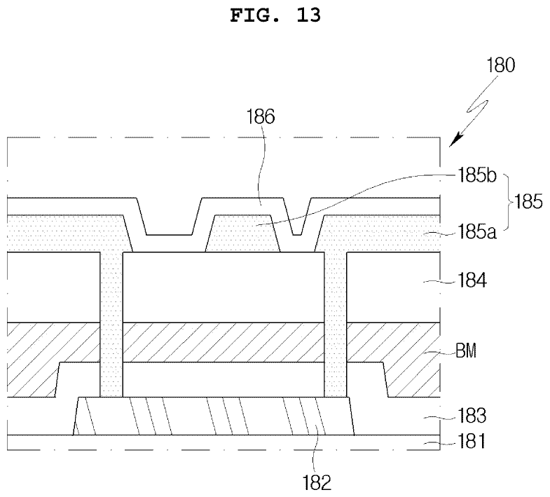

First, a cross section of the display area DA of the display panel 100 will be described with reference to FIGS. 12 and 13.

FIG. 12 is a cross-sectional view of a display area in the display panel according to one embodiment of the present disclosure. FIG. 13 is a cross-sectional view of a touch part of FIG. 12 taken at a different angle.

Referring to FIGS. 1, 12, and 13, the display panel 100 can include a plurality of pixels PX. The pixel PX can include a plurality of first pixels PX1 and a plurality of second pixels PX2. The first pixel PX1 and the second pixel PX2 can be disposed in the display area DA.

For example, the first pixel PX1 and the second pixel PX2 can be disposed repeatedly in the first direction DR1. The first pixel PX1 and the second pixel PX2 can be disposed alternately repeatedly in the second direction DR2. However, the embodiments of the present disclosure are not limited thereto.

The first pixel PX1 and the second pixel PX2 can each include light-emitting areas EA1 and EA2 and non-light-emitting areas NEA1 and NEA2.

The first pixel PX1 can include a first light-emitting area EA1 and a first non-light-emitting area NEA1 disposed around the first light-emitting area EA1. The second pixel PX2 can include a second light-emitting area EA2 and a second non-light-emitting area NEA2 disposed around the second light-emitting area EA2.

The display panel 100 can include a substrate 101, a thin film transistor 120, a storage electrode 140, a light-emitting part 150, an encapsulation part 170, and a touch part 180 in the display area DA. However, the embodiments of the present disclosure are not limited thereto.

Each pixel PX can include the thin film transistor 120, the storage electrode 140, and the light-emitting part 150.

The substrate 101 can provide a space in which various components can be disposed thereon. The substrate 101 can correspond to a flat surface shape of the display panel 100 of FIG. 1. For example, the substrate 101 can be formed to include a notch part NCP. The substrate 101 can include the display area DA and the non-display area NDA of the display panel 100 in substantially the same manner.

The substrate 101 can include one or more plastic materials, but is not limited thereto, and can include a glass material.

The substrate 101 can be a multi-substrate including a plurality of substrates of a first substrate 101a, a second substrate 101b, and a third substrate 103c each including a plastic material, such as polyimide, but the embodiments of the present disclosure are not limited thereto. For example, the substrate 101 can be a single substrate formed of a single layer.

The substrate 101 can include a rigid substrate. However, the embodiments of the present disclosure are not limited thereto, and the substrate 101 can include a flexible substrate.

The buffer layer 102 can be disposed on the substrate 101. The buffer layer 102 can minimize or delay the diffusion of moisture or oxygen permeating the substrate 101. Although the buffer layer 102 can be formed by alternately stacking silicon nitride (SiNₓ) and silicon oxide (SiOₓ) at least once, the embodiments of the present disclosure are not limited thereto.

Although the disclosure describes that the buffer layer 102 is formed as multiple layers formed of three layers, the number of layers forming the buffer layer 102 is not limited thereto, and the buffer layer 102 can be formed as a single layer.

A light shielding layer 126 can be disposed on the buffer layer 102. The light shielding layer 126 can prevent light from being transmitted to a semiconductor layer 123 of the thin film transistor 120. For example, the semiconductor layer 123 can be disposed to overlap the light-shielding layer 126. The light shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

A first insulating layer 103 can be disposed on the light shielding layer 126. The first insulating layer 103 can prevent a short circuit between a component of the thin film transistor 120 and the light shielding layer 126. The first insulating layer 103 can be formed of the same material as the buffer layer 102, but the embodiments of the present disclosure are not limited thereto. For example, the first insulating layer 103 can be formed of an inorganic material, such as silicon nitride (SiNₓ) or silicon oxide (SiOₓ), but the embodiments of the present disclosure are not limited thereto.

The thin film transistor 120 can be disposed on the first insulating layer 103. The thin film transistor 120 can include a source electrode 121, a gate electrode 122, a semiconductor layer 123, and a drain electrode 124.

The semiconductor layer 123 can be disposed on the first insulating layer 103. The semiconductor layer 123 can include a metal oxide semiconductor, such as indium-gallium-zinc oxide (IGZO), and a silicon-based semiconductor material, such as amorphous silicon or polycrystalline silicon, but the embodiments of the present disclosure are not limited thereto. The semiconductor layer 123 can include a source area, a drain area, and a channel area between the source area and the drain area.

Since the polycrystalline semiconductor layer has higher mobility than the amorphous semiconductor layer and the oxide semiconductor layer, consumed power can be less, and reliability can be excellent. Accordingly, a driving transistor can be formed of a polycrystalline semiconductor layer, but the embodiments of the present disclosure are not limited thereto.

A second insulating layer 104 can be disposed on the semiconductor layer 123. The second insulating layer 104 can be formed of the same material as the first insulating layer 103, but the embodiments of the present disclosure are not limited thereto. The second insulating layer 104 can prevent a short circuit between the semiconductor layer 123 and another component of the thin film transistor 120.

The gate electrode 122 can be disposed on the second insulating layer 104. The gate electrode 122 can be disposed on the second insulating layer 104 to overlap the channel area of the semiconductor layer 123. The gate electrode 122 can be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The gate electrode 122 can be disposed along with the gate line, but the embodiments of the present disclosure are not limited thereto.

A third insulating layer 105 can be disposed on the gate electrode 122. The third insulating layer 105 can be formed of the same material as the first insulating layer 103 or the second insulating layer 104, but the embodiments of the present disclosure are not limited thereto.

The storage electrode 140 can be disposed to be spaced apart from the thin film transistor 120. The storage electrode 140 can include a first storage electrode 141 and a second storage electrode 142.

The first storage electrode 141 can be formed of the same material as the gate electrode 122 and formed on the same layer, but the embodiments of the present disclosure are not limited thereto.

The second storage electrode 142 can be disposed on the first storage electrode 141. The second storage electrode 142 can be disposed on the third insulating layer 105, and the third insulating layer 105 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

A fourth insulating layer 106 can be disposed on the second storage electrode 142. The fourth insulating layer 106 can be formed of the same material as the first insulating layer 103, the second insulating layer 104, or the third insulating layer 105, but the embodiments of the present disclosure are not limited thereto.

The source electrode 121 and the drain electrode 124 can be disposed on the fourth insulating layer 106.

The source electrode 121 and the drain electrode 124 can be electrically connected to the semiconductor layer 123 through contact holes. The source electrode 121 and the drain electrode 124 can be formed of a metallic material. For example, the source electrode 121 and the drain electrode 124 can be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The source electrode 121 and the drain electrode 124 can be disposed along with the data line. For example, the data line can be formed of the same material as the source electrode 121 and the drain electrode 124 and formed on the same layer, but the embodiments of the present disclosure are not limited thereto.

The thin film transistor 120 can be a driving transistor, and the display panel 100 can further include a switching transistor, but the embodiments of the present disclosure are not limited thereto.

A first protective layer 111 can be disposed on the source electrode 121 and the drain electrode 124.

The first protective layer 111 can planarize an upper portion of the thin film transistor 120 and protect the thin film transistor 120. The first protective layer 111 can be formed of an organic material. For example, the first protective layer 111 can be formed of an organic material containing an acrylic resin, an epoxy resin, a phenolic resin, a polyamide resin, or a polyimide resin, but the embodiments of the present disclosure are not limited thereto.

A second protective layer 112 can be disposed on the first protective layer 111. The second protective layer 112 can be formed of the same material as the first protective layer 111, but the embodiments of the present disclosure are not limited thereto.

A connection electrode 145 can be disposed between the first protective layer 111 and the second protective layer 112.

The connection electrode 145 can electrically connect the thin film transistor 120 to the light-emitting part 150. The connection electrode 145 can be formed of the same material as the source electrode 121 and the drain electrode 124, but the embodiments of the present disclosure are not limited thereto.

The connection electrode 145 can come into contact with the drain electrode 124 through the contact hole formed in the first protective layer 111 and can be electrically connected to the drain electrode 124.

The connection electrode 145 can be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include an anode electrode 151, an organic layer 152, and a cathode electrode 153.

The anode electrode 151 can be disposed on the second protective layer 112. The anode electrode 151 can be electrically connected to the thin film transistor 120 through contact holes formed in the first protective layer 111 and the second protective layer 112.

The anode electrode 151 can be a reflective electrode that reflects light, but the embodiments of the present disclosure are not limited thereto. The anode electrode 151 can include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

For example, the cathode electrode 153 can include a material, such as indium tin oxide (ITO) or indium zinc oxide (IZO), but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto.

The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include the organic light-emitting layer. The organic layer 152 can be a white light-emitting layer, but the embodiments of the present disclosure are not limited thereto. The organic layer 152 can be a white light-emitting layer, but the embodiments of the present disclosure are not limited thereto.

The cathode electrode 153 can be disposed on the organic layer 152. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

The capping layer 156 can be further disposed on the cathode electrode 153. The capping layer 156 can minimize damage to the cathode electrode 153 of the light-emitting element EL and the organic layers 152 located below the cathode electrode 153 from an external light source. The capping layer 156 can be formed of an organic or inorganic film.

The capping layer 156 can be disposed using a material, such as LiF etc., as an inorganic film and can further include an organic film, but the embodiments of the present disclosure are not limited thereto. For example, the capping layer 156 can be formed of the stacking structure of an organic film and an inorganic film, and a thickness of the organic film can differ from a thickness of the inorganic film. In this case, the thickness of the organic film can be larger than the thickness of the inorganic film. As another example, the capping layer 156 can be formed of two or more layers by stacking materials having different refractive indices. Accordingly, it is possible to increase the light efficiency of the display panel 100.

A bank 154 can be disposed to expose the anode electrode 151. The bank 154 can define an opening (or a light-emitting area EA) of the pixel PX and can be disposed to cover an edge of the anode electrode 151. The organic layer 152 can be disposed in the opening of the pixel PX. For example, the organic layer 152 can be disposed on the anode electrode 151 exposed by the bank 154.

However, the embodiments of the present disclosure are not limited thereto, and the organic layer 152 can be disposed both in the opening (the light-emitting area EA) of the pixel PX and on the bank 154. For example, the organic layer 152 can be disposed in the entirety of the display area DA of the display panel 100.

The bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be an opaque bank. When the bank 154 is formed of a material containing black pigment or black dye, it is possible to shield external light or light reflected from the outside, thereby further increasing the luminance of the display apparatus.

A spacer can be further disposed on the bank 154. The spacer can be formed of the same material as the bank 154, but the embodiments of the present disclosure are not limited thereto. The spacer can prevent sagging of a mask during a mask process, thereby suppressing or preventing defects, such as imprinting, scratching, etc., on the display panel 100.

The encapsulation part 170 can be disposed on the bank 154 or the light-emitting part 150. The encapsulation part 170 can include one or more insulating layers. For example, the encapsulation part 170 can include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 can include one or more inorganic layers and one or more organic layers. For example, the first inorganic encapsulation layer 171 and the second inorganic encapsulation layer 173 can include an inorganic material, and the organic encapsulation layer 172 can include an organic material, but the embodiments of the present disclosure are not limited thereto.

The first inorganic encapsulation layer 171 and the second inorganic encapsulation layer 173 can be disposed to extend around the dam part DMP, and the organic encapsulation layer 172 can be ended inside the dam part DMP. For example, the organic encapsulation layer 172 can be disposed inside an area surrounded by the dam part DMP without extending beyond the dam part DMP.

The touch part 180 can be disposed on the encapsulation part 170. The touch part 180 can include a touch buffer layer 181, a first touch electrode 182, a first touch insulating layer 183, a black matrix BM, a second touch insulating layer 184, a second touch electrode 185, and a third touch insulating layer 186.

The touch buffer layer 181 can be disposed on the encapsulation part 170. For example, the touch buffer layer 181 can be disposed on the second inorganic encapsulation layer 173. The touch buffer layer 181 can be made of the same material as the buffer layer 102, but the embodiments of the present disclosure are not limited thereto.

The first touch electrode 182 can be disposed on the touch buffer layer 181.

The first touch insulating layer 183 can be disposed on the first touch electrode 182. The first touch insulating layer 183 can be formed of silicon oxide (SiOₓ), silicon nitride (SiNₓ), or multiple layers thereof, but the embodiments of the present disclosure are not limited thereto.

The black matrix BM can be disposed on the first touch insulating layer 183. The black matrix BM can include materials capable of absorbing light. The black matrix BM can include a black pigment or dye, but is not limited thereto. The black matrix BM can prevent a defect, such as light leakage that can occur between the pixels PX.

The second touch insulating layer 184 can be disposed on the black matrix BM. The second touch insulating layer 184 can include an organic insulating material. For example, the second touch insulating layer 184 can be formed of photo acryl, benzocyclobutene (BCB), polyimide (PI), or polyamide (PA), but is not limited thereto.

The second touch electrode 185 can be disposed on the second touch insulation layer 184. The second touch electrode 185 can include a la touch electrode 185a extending in the first direction DR1 and a 1b touch electrode 185b extending in the second direction DR2 different from the first direction.

The first touch electrode 182 can be electrically connected to a 2a touch electrode 185a through a contact hole formed in the second touch insulating layer 184. For example, the 2a touch electrode 185a and the first touch electrode 182 can extend in the first direction DR1.

The first touch electrode 182 and the second touch electrode 185 can include a metallic material. For example, the first touch electrode 185 and the second touch electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

One of the first touch electrode 182 and the second touch electrode 185 can include a function of detecting touch, and the other can include a function of driving touch, but the embodiments of the present disclosure are not limited thereto.

The third touch insulating layer 186 can be disposed on the second touch electrode 185. The third touch insulating layer 186 can be formed of the same material as the first touch insulating layer 183, but is not limited thereto.

A microlens ML (ML1 and ML2) can be disposed on the third touch insulating layer 186.

A first microlens ML1 can correspond to the first pixel PX1, and a second microlens ML2 can correspond to the second pixel PX2.

The microlens ML can include a hemispherical or semi-cylindrical shape, but is not limited thereto. The shape of the microlens ML can vary according to the size, shape, etc. of the light-emitting area EA.

The microlenses ML1 and ML2 can control paths of light emitted from the pixel PX1 and PX2, respectively. The microlenses ML1 and ML2 can control the paths of the light emitted from the pixels PX1 and PX2 in different directions.

For example, the first microlens ML1 can control the light emitted from the first pixel PX1 to travel to the other side in the first direction DR1 in a plan view, and the second microlens ML2 can control the light emitted from the second pixel PX2 to travel to the other side in the first direction DR1 in a plan view.

Accordingly, the pixels PX1 and PX2 can display different images and videos, and the display apparatus 1 (see FIG. 1) can display two different images and videos according to a viewing angle.

When the display apparatus 1 (see FIG. 1) is used for a vehicle, a screen displayed to the driver in the driver's seat and a screen displayed to the co-driver in the passenger's seat can be controlled separately, and different screens can be displayed to the driver and the co-driver.

However, the embodiments of the present disclosure are not limited thereto, and one of the pixels PX1 and PX2 can provide a screen displayed to both the driver and the co-driver.

In addition, by arranging the microlens ML (ML1 and ML2), it is possible to secure a wide viewing angle characteristic, increase luminance, and block leaked light, reflected light, etc., thereby preventing light leakage.

The microlens ML can include a division line DV (DV1 and DV2). The division line DV can include a first division line DV1 and a second division line DV2.

The division line DV can refer to a virtual line that bisects the microlens ML. The microlens ML can be divided into two substantially equal parts through the division line DV, but is not limited thereto. The two parts of the microlens ML divided by the division line DV can include a symmetrical shape, but is not limited thereto, and the two parts of the microlens ML divided by the division line DV can have different shapes and sizes.

The division line DV (DV1 and DV2) can be misaligned with the center EC (EC1 and EC2) of the light-emitting area EA, but is not limited thereto.

A first center EC1 can refer to the center of the first light-emitting area EA1 of the first pixel PX1, and a second center EC2 can refer to the center of the second light-emitting area EA2 of the second pixel PX2.

The first microlens ML1 can include the first division line DV1, and the second microlens ML2 can include the second division line DV2.

In addition, at least a part of the light-emitting part 150 can be disposed to be inclined in the thickness direction (the third direction DR3).

Specifically, in the area in which the light-emitting part 150 is disposed, a part of an upper surface of the second protective layer 112 can be formed to have inclination. The light-emitting part 150 can be disposed on the second protective layer 112 of which at least a part is inclined. Accordingly, at least a part of each of the anode electrode 151 and the organic layer 152 can be tilted. The at least a part of each of the anode electrode 151 and the organic layer 152 can be tilted (inclined) toward the microlens ML.

Each of the anode electrode 151 and the organic layer 152 can be disposed on the second protective layer 112 of which at least a part is inclined. The organic layer 152 can be disposed on the second protective layer 112 of which the entire area is inclined, but is not limited thereto.

The anode electrode 151 and the organic layer 152 that are disposed on the inclined second protective layer 112 can be disposed to be inclined (tilted) corresponding to the inclined second protective layer 112. Accordingly, a part of the cathode electrode 153 disposed on the organic layer 152 can be disposed to be inclined.

The anode electrode 151 and the organic layer 152 can be disposed to be inclined in the thickness direction (the third direction DR3) of the display panel 100 in the first light-emitting area EA1, the second light-emitting area EA2, and surrounding areas thereof. An upper surface of the anode electrode 151 and an upper surface of the organic layer 152 can be inclined in the thickness direction (the third direction DR3) of the display panel 100. A direction in which the upper surface of the anode electrode 151 and the upper surface of the organic layer 152 face can be inclined in the thickness direction (the third direction DR3) of the display panel 100.

The upper surface of the anode electrode 151 and the upper surface of the organic layer 152 can be inclined with respect to an upper surface of the first protective layer 111.

The anode electrode 151 and the organic layer 152 of the first pixel PX1 can be inclined in a different direction from the anode electrode 151 and the organic layer 152 of the second pixel PX2. For example, in the first light-emitting area EA1, the second light-emitting area EA2, and the surrounding areas thereof, the directions in which the anode electrode 151 and the organic layer 152 are inclined can be opposite.

The upper surface of the anode electrode 151 and the upper surface of the organic layer 152 of the first pixel PX1 can be inclined toward the first microlens ML1, and the upper surface of the anode electrode 151 and the upper surface of the organic layer 152 of the second pixel PX2 can be inclined toward the second microlens ML2.

Accordingly, light emitted from each pixel PX can be inclined in the thickness direction (the third direction DR3) of the display panel 100.

The first center EC1 of the first light-emitting area EA1 of the first pixel PX1 and the first division line DV1 of the first microlens ML1 disposed on the first pixel PX1 can be misaligned. The second center EC2 of the second light-emitting area EA2 of the second pixel PX2 and the second division line DV2 of the second microlens ML2 disposed on the second pixel PX2 can be misaligned.

A direction in which the first center EC1 and the first division line DV1 are misaligned can differ from a direction in which the second center EC2 and the second division line DV2 are misaligned. For example, the direction in which the first center EC1 and the first division line DV1 are misaligned and the direction in which the second center EC2 and the second division line DV2 are misaligned can be opposite, but are not limited thereto.

The opening (or the light-emitting area EA) of the pixel PX and the light-emitting part 150 disposed around the opening can be disposed to be inclined in the thickness direction (the third direction DR3), and light L1 and L2 emitted from the light-emitting part 150 can travel in a direction inclined with respect to the thickness direction (the third direction DR3).

As the microlens ML and the light-emitting area EA are misaligned, even when the light L1 and L2 emitted from the light-emitting part 150 travels while tilted with respect to the thickness direction (the third direction DR3), each light L1 or L2 can travel toward the microlens ML of each pixel PX.

The first pixel PX1 can emit the light L1 inclined to the left in a cross-sectional view. The second pixel PX2 can emit the light L2 to be inclined to the right in a cross-sectional view.

The direction and degree of the misalignment between the microlens ML and the light-emitting area EA can vary according to the traveling direction of the light emitted from each pixel PX1 or PX2.

As the light-emitting part 150 of each pixel PX (PX1 or PX2) is inclined, the path of the light emitted from each pixel PX1 or PX2 can be more easily controlled, and different images and videos can be displayed more clearly according to a viewing angle.

A lens protective layer 190 can be disposed on the microlens ML (ML1 and ML2). The lens protective layer 190 can include an organic insulating material, but is not limited thereto. The lens protective layer 190 can protect the microlens ML by covering the microlens ML.

A refractive index of the lens protective layer 190 can be smaller than a refractive index of the microlens ML. Accordingly, due to a difference in refractive index between the microlens ML and the lens protective layer 190, light passing through the microlens ML can be prevented from being reflected toward the substrate 101.

Hereinafter, a cross-sectional structure of the non-display area NDA of the display apparatus 1 will be described. The same content as that described in the cross-sectional structure of the display area DA will be briefly described or omitted.

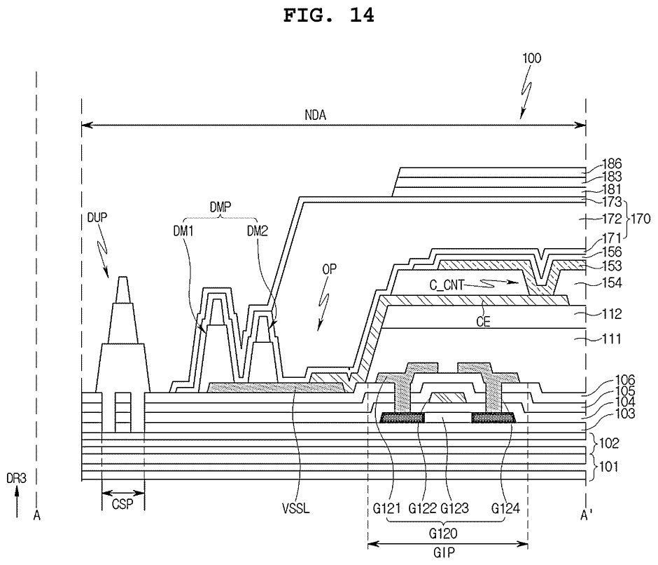

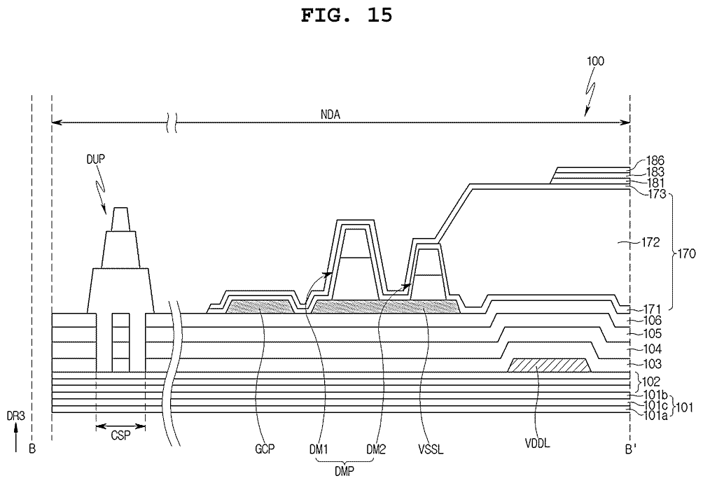

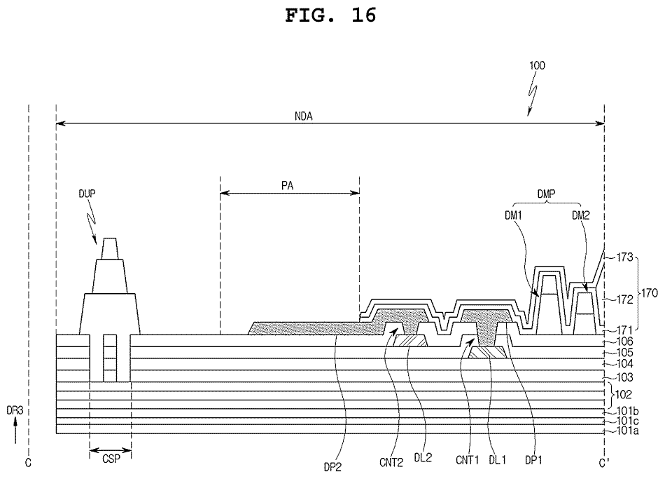

FIG. 14 is a cross-sectional view along line A-A′ in FIG. 1. FIG. 15 is a cross-sectional view along line B-B′ in FIG. 3. FIG. 16 is a cross-sectional view along line C-C′ in FIG. 3.

First, a cross section of the non-display area NDA will be described with reference to FIGS. 14 to 16.

Subsequently, referring further to FIGS. 1, 3, and 14 to 16, the display panel 100 can further include a gate control transistor G120, the low-potential voltage line VSSL, the dam part DMP, the plurality of pads GCP, VSSP, VDDP, and DP disposed in the pad area PA, the data line DL (DL1 and DL2), and a crack prevention pattern CSP, which are disposed in the non-display area NDA.

The gate control transistor G120 can have substantially the same configuration as the thin film transistor 120 of the pixel PX and can be formed along with the thin film transistor 120 of the pixel PX by the same process, but is not limited thereto.

The gate control transistor G120 can include a control source electrode G121, a control gate electrode G122, a control semiconductor layer G123, and a control drain electrode G124.

A light shielding layer can be further disposed under the gate control transistor G120. One of the control source electrode G121 and the control drain electrode G124 can be electrically connected in contact with the light shielding layer, but is not limited thereto.

The gate control pad GCP can be disposed on the fourth insulating layer 106. The low-potential voltage line VSSL can be formed of the same metal layer as the source electrode 121 and the drain electrode 124 of the thin film transistor 120, but is not limited thereto.

The low-potential voltage line VSSL can be disposed on the fourth insulating layer 106. The low-potential voltage line VSSL can be formed of the same metal layer as the source electrode 121 and the drain electrode 124 of the thin film transistor 120, but is not limited thereto.

The display panel 100 can further include a low-potential connection electrode CE. The low-potential connection electrode CE can connect the low-potential voltage line VSSL to the cathode electrode 153.

The low-potential connection electrode CE can be disposed on the second protective layer 112. The bank 154 can be disposed on the low-potential connection electrode CE. The low-potential connection electrode CE can be disposed on the same layer as the anode electrode 151 and can include the same material as the anode electrode 151, and the low-potential connection electrode CE and the anode electrode 151 can be formed together using one mask by the same process, but the embodiments of the present disclosure are not limited thereto.

The display panel 100 can further include an exposed part OP. The exposed part OP can expose at least a part of the low-potential voltage line VSSL by recessing the first protective layer 111 and the second protective layer 112.

The exposed part OP can be defined by the first protective layer 111 and the second protective layer 112. The exposed part OP can be defined by a side surface of the first protective layer 111, a side surface of the second protective layer 112, and a side surface of a second dam DM2.

The low-potential connection electrode CE can be electrically connected in contact with the low-potential voltage line VSSL exposed in the exposed part OP. At least a part of the low-potential connection electrode CE can be disposed on the second protective layer 112 and can extend from the second protective layer 112 toward the low-potential voltage line VSSL.

The low-potential connection electrode CE can be further disposed on the side surface of the first protective layer 111 that defines the exposed part OP and the side surface of the second protective layer 112 and can be further disposed on the fourth insulating layer 106 and the low-potential voltage line VSSL that are exposed by the exposed part OP. Accordingly, the low-potential connection electrode CE can come into contact with the low-potential voltage line VSSL.

The low-potential connection electrode CE can be electrically connected to the cathode electrode 153. The low-potential connection electrode CE and the cathode electrode 153 can be electrically connected in contact with each other through a low-potential contact hole C_CNT in an overlapping area. The low-potential contact hole C_CNT can be defined by passing through the bank 154 in the area in which the low-potential connection electrode CE and the cathode electrode 153 overlap each other and can expose the low-potential connection electrode CE.

The dam part DMP can include a first dam DM1 and the second dam DM2. The first dam DM1 and the second dam DM2 can overlap a first low-potential voltage line VSSL1 or a second low-potential voltage line VSSL2.

In the non-display area NDA, the first dam DM1 and the second dam DM2 can overlap the first low-potential voltage line VSSL1. In the non-display area NDA, the first dam DM1 and the second dam DM2 can overlap the second low-potential voltage line VSSL2.

The first dam DM1 can be disposed outside the second dam DM2, but is not limited thereto.

The first dam DM1 can be formed in a multilayered structure. Each layer of the first dam DM1 can include the same material as the second protective layer 112 and the bank 154, and each layer of the first dam DM1, the second protective layer 112, and the bank 154 can be formed together using one mask by the same process, but the embodiments of the present disclosure are not limited thereto.

The second dam DM2 can be formed in a multilayered structure. Each layer of the second dam DM2 can include the same material as the bank 154 and the spacer, and each layer of the second dam DM2, the bank 154, and the spacer can be formed together using one mask by the same process, but the embodiments of the present disclosure are not limited thereto.

The crack protection pattern CSP can be disposed at an outermost edge of the non-display area NDA. The crack protection pattern CSP can be defined by recessing at least one of the inorganic films disposed on the substrate 101.

For example, the crack protection pattern CSP can be defined by recessing the first insulating layer 103, the second insulating layer 104, the third insulating layer 105, and the fourth insulating layer 106, but is not limited thereto.

A crack dummy pattern DUP can be further disposed on the crack protection pattern CSP. The crack dummy pattern DUP can fill the recessed crack protection pattern CSP. The crack dummy pattern DUP can be formed of multiple layers. For example, the crack dummy pattern DUP can be formed of three layers. Layers of the crack dummy pattern DUP can include the same material as the first protective layer 111, the second protective layer 112, and the bank 154.

The high-potential voltage line VDDL can be disposed on the buffer layer 102 and covered by the first insulating layer 103. The high-potential voltage line VDDL can include the same material as the light shielding layer 126, and the high-potential voltage line VDDL and the light shielding layer 126 can be formed together using one mask by the same process, but the embodiments of the present disclosure are not limited thereto.

The high-potential voltage pad VDDP can be disposed on the same layer as the source electrode 121 and the drain electrode 124 and can include the same material as the source electrode 121 and the drain electrode 124, and the high-potential voltage pad VDDP, the source electrode 121, and the drain electrode 124 can be formed together using one mask by the same process, but the embodiments of the present disclosure are not limited thereto.

In this case, the high-potential voltage pad VDDP can be electrically connected in contact with the high-potential voltage line VDDL through the high-potential contact hole S CNT that exposes the high-potential voltage line VDDL.

However, the embodiments of the present disclosure are not limited thereto, and the high-potential voltage line VDDL can be disposed on the same layer as the source electrode 121 and the drain electrode 124 and can include the same material as the source electrode 121 and the drain electrode 124, and the high-potential voltage line VDDL, the source electrode 121, and the drain electrode 124 can be formed together using one mask by the same process.

The first data pad DP1 and the second data pad DP2 can be disposed on the fourth insulating layer 106. The first data pad DP1 and the second data pad DP2 can be disposed on the same layer as the source electrode 121 and the drain electrode 124 and can include the same material as the source electrode 121 and the drain electrode 124, and the first data pad DP1, the second data pad DP2, the source electrode 121, and the drain electrode 124 can be formed together using one mask by the same process, but the embodiments of the present disclosure are not limited thereto.

The first data line DL1 can be disposed on the second insulating layer 104 and covered by the third insulating layer 105. The first data line DL1 can include the same material as the gate electrode 122, and the first data line DL1 and the gate electrode 122 can be formed together using one mask by the same process, but the embodiments of the present disclosure are not limited thereto.

The second data line DL2 can be disposed on the third insulating layer 105 and covered by the fourth insulating layer 106. The second data line DL2 can include the same material as the second storage electrode 142, and the second data line DL2 and the second storage electrode 142 can be formed together using one mask by the same process, but the embodiments of the present disclosure are not limited thereto.

The first data line DL1 can be electrically connected in contact with the first data pad DP1 through the first data contact hole CNT1. The second data line DL2 can be electrically connected in contact with the second data pad DP2 through the second data contact hole CNT2.

The crack protection pattern CSP can be disposed outside the pad area PA. The crack protection pattern CSP can be disposed between the pad area PA and an end portion of the non-display area NDA.

However, the plurality of pads VSSP, VDDP, and DP may not be covered by a plurality of inorganic films. The plurality of inorganic films disposed on the fourth insulating layer 106 can expose the plurality of pads GCP, VSSP, VDDP, and DP. The plurality of inorganic films disposed on the fourth insulating layer 106 may not be disposed in the pad area PA.

Accordingly, the flexible film COF can have at least a part disposed to overlap the pad area PA and attached to the display panel 100, and the flexible film COF can be electrically connected in contact with the plurality of pads GCP, VSSP, VDDP, and DP of the pad area PA.

Hereinafter, other embodiments of the present disclosure will be described. For contents that are substantially the same as those described with reference to FIGS. 1 to 16 among components included in other embodiments, the same reference numerals are given, and overlapping contents can be omitted or briefly described.

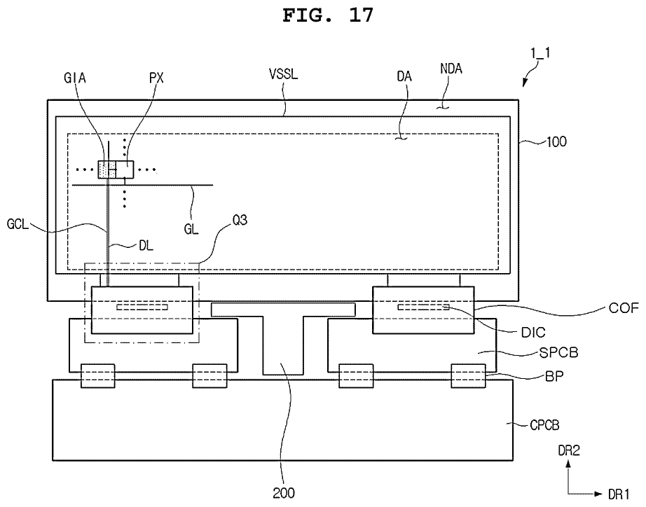

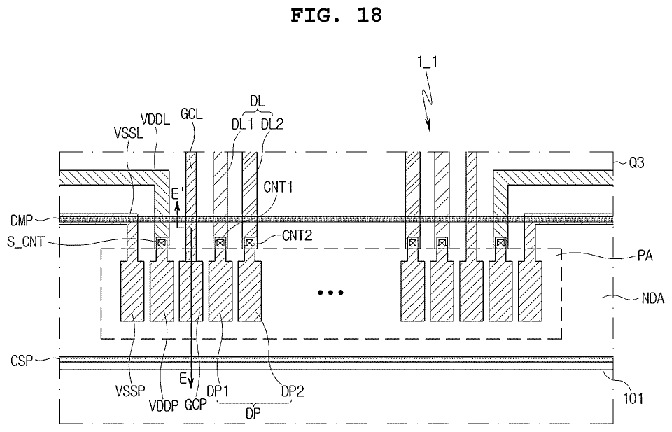

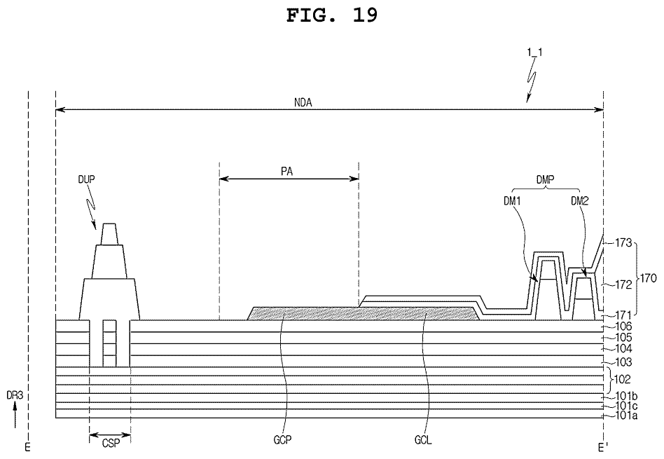

FIG. 17 is a plan view of the display apparatus according to another embodiment of the present disclosure. FIG. 18 is an enlarged view of area Q3 in FIG. 17. FIG. 19 is a cross-sectional view along line E-E′ in FIG. 18.

FIG. 18 is a view of area Q3 of a display apparatus 1_1 according to another embodiment, from which the flexible film COF, the source printed circuit board SPCB, the drive IC DIC, etc. are omitted.

Referring to FIGS. 17 to 19, in the display apparatus 1_1 according to the present embodiment, a separate gate driving unit GIP (see FIG. 1) may not be disposed in the non-display area NDA, and a pixel gate driving unit GIA can be disposed in the display area DA.

The pixel gate driving unit GIA can be provided as a plurality of pixel gate drivers, and each pixel gate driving unit GIA can be connected to each of the plurality of pixels PX. The pixel gate driving unit GIA can be disposed around the pixel PX. The pixel gate driving unit GIA can be disposed between adjacent pixels PX.

For example, the pixel gate driving unit GIA can be disposed between adjacent pixels PX in the first direction DR1. The pixel PX and the pixel gate driving unit GIA can be alternately repeatedly disposed in the first direction DR1. The pixel PX can be continuously repeatedly disposed in the second direction DR2. The pixel gate driving unit GIA can be continuously repeatedly disposed in the second direction DR2.

The pixel gate driving unit GIA can perform substantially the same role as the gate driving unit GIP (see FIG. 1). The pixel gate driving unit GIA can include at least one transistor.

The pixel gate driving unit GIA can be electrically connected to an adjacent pixel PX.

The pixel gate driving unit GIA can receive a gate control signal from the drive IC DIC through the gate control line GCL. The pixel gate driving unit GIA can generate a scan signal and a light-emitting signal (or a light-emitting control signal) based on the gate control signal. Accordingly, the driving of the adjacent pixel PX can be controlled.

Since the pixel gate driving unit GIA is disposed in the display area DA, it is possible to minimize the non-display area NDA or the bezel area, thereby providing an improved aesthetic feeling to a user.

The gate control line GCL can be disposed in the non-display area NDA and the display area DA. The gate control line GCL can be disposed in the non-display area NDA, but is not limited thereto. The gate control line GCL can be disposed in an extension direction of the non-display area NDA.

The gate control line GCL can be partially disposed in the non-display area NDA and can extend from the non-display area NDA to the pixel gate driving unit GIA of the display area DA. The gate control line GCL can be electrically connected to the plurality of pixel gate driving units GIA disposed in the display area DA.

The gate control pad GCP can be disposed in the pad area PA. In the pad area PA, the gate control pad GCP is illustrated as being disposed between the high-potential voltage pad VDDP and the data pad DP, but is not limited thereto, and the arrangement location of the gate control pad GCP can vary according to a design.

The gate control pad GCP can include the same material as the gate control line GCL, but is not limited thereto. The gate control pad GCP and the gate control line GCL can be formed integrally, but are not limited thereto.

The gate control pad GCP and the gate control line GCL can be disposed on the fourth insulating layer 106. The gate control pad GCP and the gate control line GCL can be disposed on the same layer as the source electrode 121 (see FIG. 12) and the drain electrode 124 (see FIG. 12) and can include the same material as the source electrode 121 and the drain electrode 124, and the gate control pad GCP, the gate control line GCL, the source electrode 121, and the drain electrode 124 can be formed together using one mask by the same process, but the embodiments of the present disclosure are not limited thereto.

In the pad area PA, the plurality of pads VSSP, VDDP, DP, and GCP may not be covered by the plurality of inorganic films. The plurality of inorganic films disposed on the fourth insulating layer 106 can expose the plurality of pads VSSP, VDDP, DP, and GCP. The plurality of inorganic films disposed on the fourth insulating layer 106 may not be disposed in the pad area PA.

Accordingly, in the pad area PA, the plurality of pads VSSP, VDDP, DP, and GCP disposed on the fourth insulating layer 106 can be exposed, and the display panel 100 can be adhered to the flexible film COF and electrically connected to the flexible film COF.

Since the gate driving unit GIP (see FIG. 1) is omitted from the non-display area NDA and the pixel gate driving unit GIA is disposed in the display area DA, the non-display area NDA can be reduced, thereby reducing the bezel area and increasing the display area DA.

In this case, the source printed circuit board SPCB and the control printed circuit board CPCB can be fixed by the guide holder 200. Accordingly, even when an external impact and/or shaking are transferred to the display apparatus 1_1, it is possible to suppress, minimize or prevent defects due to the separation of the source printed circuit board SPCB and the control printed circuit board CPCB.

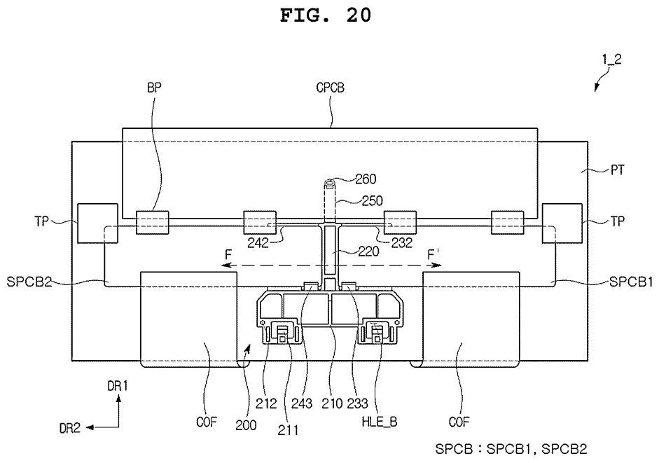

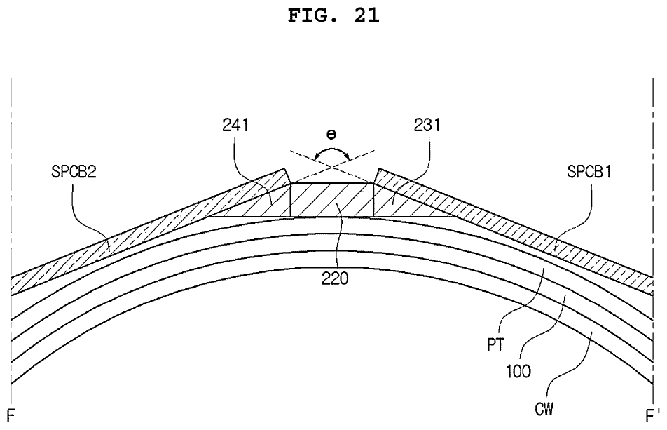

FIG. 20 is a plan view of the display apparatus according to another embodiment of the present disclosure. FIG. 21 is a cross-sectional view along line F-F′ in FIG. 20.

For convenience of description, FIG. 20 illustrates only the source printed circuit board SPCB fixed to the guide holder.

Referring to FIGS. 20 and 21, an angle θ formed between one surface of the first source seating portion 231 and one surface of the second source seating portion 241 of the guide holder 200 according to the present embodiment can be smaller than 180°. An angle formed between the first source printed circuit board SPCB1 seated on the one surface of the first source seating portion 231 and the second source printed circuit board SPCB2 seated on the one surface of the second source seating portion 241 can be smaller than 180°.

A display apparatus 1_2 can be a curved display apparatus that is curved to have a curvature. When the display apparatus 1_2 is a curved display apparatus, the heat dissipation sheet PT, the display panel 100, and a cover window CW can all be curved to have a curvature.

The display apparatus 1_2 can further include the cover window CW, and the cover window CW can protect the display panel 100.

When the display apparatus 1_2 is a curved display apparatus, since the angle θ formed between the one surface of the first source seating portion 231 and the one surface of the second source seating portion 241 is smaller than 180°, stress applied to the flexible film COF connecting the source printed circuit board SPCB to the display panel 100 can be reduced.

In this case, the source printed circuit board SPCB and the control printed circuit board CPCB can be fixed by the guide holder 200. Accordingly, even when an external impact and/or shaking are transferred to the display apparatus 1_2, it is possible to suppress, minimize or prevent defects due to the separation of the source printed circuit board SPCB and the control printed circuit board CPCB.

Since the angle θ formed between the one surface of the first source seating portion 231 of the guide holder 200 and the one surface of the second source seating portion 241 is formed to be smaller than 180°, even when the display apparatus 1_2 is bent to have a curvature, the flexible film COF can be more tightly attached and fixed to the display panel 100 and the source printed circuit board SPCB.

A display apparatus according to various embodiments of the present disclosure can be described as follows.

A display apparatus according to embodiments of the present disclosure includes a display panel, a flexible film connected to the display panel, a source printed circuit board connected to the flexible film, a connection member connected to the printed circuit board, a control printed circuit board connected to the connection member, and a guide holder that fixes the source printed circuit board and the control printed circuit board, in which the source printed circuit board and the control printed circuit board overlap each other under the display panel.

According to various embodiments of the present disclosure, the guide holder can include a body portion, a first control hook disposed on the body portion, a base portion protruding from the body portion in a second direction, a protrusion protruding and extending from the base portion in the second direction, and a second control hook protruding from the protrusion in a thickness direction, in which the control printed circuit board can be fixed on the body portion and the protrusion by the first control hook and the second control hook.

According to various embodiments of the present disclosure, the guide holder can further include a first seating portion extending from the base portion to one side in a first direction intersecting a second direction, a first partition curved from the first seating portion and protruding in a thickness direction, and a first source hook protruding from the body portion toward the first seating portion.

According to various embodiments of the present disclosure, the guide holder can further include a second seating portion extending from the base portion to the other side in a first direction, a second partition curved from the second seating portion and protruding in a thickness direction, and a second source hook protruding from the body portion toward the second seating portion.

According to various embodiments of the present disclosure, the source printed circuit board can be provided as a plurality of source printed circuit boards, the first source printed circuit board can be fixed on the first seating portion by the first partition and the first source hook, and the second source printed circuit board can be fixed on the second seating portion by the second partition and the second source hook.

According to various embodiments of the present disclosure, an angle formed by one surface of the first seating portion and one surface of the second seating portion can be smaller than 180 degrees.

According to various embodiments of the present disclosure, the source printed circuit board can be fixed on the first seating portion by the first partition and the first source hook.

According to various embodiments of the present disclosure, an upper surface of the body portion and an upper surface of the first seating portion can have a step.

At least a part of an area of the first control hook can have elasticity, the area being connected to the body portion.

According to various embodiments of the present disclosure, the body portion can define a body hole passing through the body portion in the thickness direction, the first control hook can be connected to the body portion, and at least a part of the first control hook can be disposed inside the body hole.

According to various embodiments of the present disclosure, the first control hook can be provided as a plurality of first control hooks, the plurality of first control hooks can be disposed at one side and the other side of the body portion in the first direction, respectively, and the first direction can intersect the second direction.

According to various embodiments of the present disclosure, the body portion can further include a body protrusion protruding from the body portion in the thickness direction, the control printed circuit board can define a substrate hole passing therethrough in the thickness direction, and the body protrusion can be inserted into the substrate hole.

According to various embodiments of the present disclosure, the source printed circuit board can be disposed between the guide holder and the control printed circuit board.

According to various embodiments of the present disclosure, the flexible film can connect the display panel to the source printed circuit board, the connection member can connect the source printed circuit board to the control printed circuit board, and the flexible film and the connection member can be bent in the thickness direction.

According to various embodiments of the present disclosure, all areas of the guide holder, the source printed circuit board, and the control printed circuit board can overlap the display panel.

According to various embodiments of the present disclosure, the display apparatus can further include a heat dissipation sheet disposed between the display panel and the source printed circuit board.

A display apparatus according to embodiments of the present disclosure includes a display panel, a heat dissipation sheet disposed under the display panel, a control printed circuit board connected to the display panel, and a guide holder disposed under the heat dissipation sheet, in which the guide holder includes a body portion, a first control hook disposed on the body portion, a base portion protruding from the body portion in a second direction, a protrusion extending from the base portion in the second direction, and a second control hook protruding from the protrusion in a thickness direction, and the control printed circuit board is fixed on the body portion and the protrusion by the first control hook and the second control hook.

According to various embodiments of the present disclosure, the guide holder can further include a first seating portion extending from the base portion to one side in a first direction intersecting a second direction, a first partition curved from the first seating portion and protruding in a thickness direction, and a first source hook protruding from the body portion toward the first seating portion.

According to various embodiments of the present disclosure, the display apparatus can further include a flexible film connected to the display panel, a source printed circuit board connected to the flexible film, a connection member connected to the printed circuit board, and a control printed circuit board connected to the connection member, in which the source printed circuit board can be fixed on a first seating portion by a first partition and a first source hook.

According to various embodiments of the present disclosure, the body portion can further include a body protrusion protruding in the thickness direction on the body portion, the control printed circuit board can define a substrate hole passing therethrough in the thickness direction, and the body protrusion can be inserted into the substrate hole.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
100: display apparatus
DA: display area
NDA: non-display area
PX: pixel
200: guide holder
210: body portion
211: first control hook
212: body protrusion
220: base portion
230: first source fixing member
240: second source fixing member
250: protrusion
260: second control hook

What is claimed is:

1. A display apparatus comprising:
a display panel;
a flexible film connected to the display panel;
a source printed circuit board connected to the flexible film;
a connection member connected to the printed circuit board;
a control printed circuit board connected to the connection member; and
a guide holder configured to fix the source printed circuit board and the control printed circuit board,
wherein the source printed circuit board and the control printed circuit board overlap each other under the display panel.

2. The display apparatus of claim 1, wherein the guide holder includes:
a body portion;
a first control hook disposed on the body portion;
a base portion protruding from the body portion in a second direction;
a protrusion protruding and extending from the base portion in the second direction; and
a second control hook protruding from the protrusion in a thickness direction, and
wherein the control printed circuit board is fixed on the body portion and the protrusion by the first control hook and the second control hook.

3. The display apparatus of claim 2, wherein the guide holder further includes:
a first seating portion extending from the base portion to one side in a first direction intersecting the second direction;
a first partition curved from the first seating portion and protruding in the thickness direction; and
a first source hook protruding from the body portion toward the first seating portion.

4. The display apparatus of claim 3, wherein the guide holder further includes:
a second seating portion extending from the base portion to another side in the first direction;
a second partition curved from the second seating portion and protruding in the thickness direction; and
a second source hook protruding from the body portion toward the second seating portion.

5. The display apparatus of claim 4, wherein the source printed circuit board is provided as a plurality of source printed circuit boards including a first source printed circuit board and a second source printed circuit board,
wherein the first source printed circuit board is fixed on the first seating portion by the first partition and the first source hook, and
wherein the second source printed circuit board is fixed on the second seating portion by the second partition and the second source hook.

6. The display apparatus of claim 4, wherein an angle formed by one surface of the first seating portion and one surface of the second seating portion is smaller than 180 degrees.

7. The display apparatus of claim 3, wherein the source printed circuit board is fixed on the first seating portion by the first partition and the first source hook.

8. The display apparatus of claim 7, wherein an upper surface of the body portion and an upper surface of the first seating portion have a step.

9. The display apparatus of claim 2, wherein at least a part of an area of the first control hook has elasticity, the area of the first control hook being connected to the body portion.

10. The display apparatus of claim 9, wherein the body portion defines a body hole passing through the body portion in the thickness direction, and
wherein the first control hook is connected to the body portion, and at least a part of the first control hook is disposed inside the body hole.

11. The display apparatus of claim 2, wherein the first control hook is provided as a plurality of first control hooks,
wherein the plurality of first control hooks are disposed at one side and another side of the body portion in a first direction, respectively, and
wherein the first direction intersects the second direction.

12. The display apparatus of claim 2, wherein the body portion further includes a body protrusion protruding from the body portion in the thickness direction,
wherein the control printed circuit board defines a substrate hole passing therethrough in the thickness direction, and
wherein the body protrusion is inserted into the substrate hole.

13. The display apparatus of claim 1, wherein the source printed circuit board is disposed between the guide holder and the control printed circuit board.

14. The display apparatus of claim 13, wherein the flexible film connects the display panel to the source printed circuit board,
wherein the connection member connects the source printed circuit board to the control printed circuit board, and
wherein the flexible film and the connection member are bent in a thickness direction.

15. The display apparatus of claim 14, wherein all areas of the guide holder, the source printed circuit board, and the control printed circuit board overlap the display panel.

16. The display apparatus of claim 13, further comprising a heat dissipation sheet disposed between the display panel and the source printed circuit board.

17. A display apparatus comprising:
a display panel;
a heat dissipation sheet disposed under the display panel;
a control printed circuit board connected to the display panel; and
a guide holder disposed under the heat dissipation sheet,
wherein the guide holder further includes:
a body portion;
a first control hook disposed on the body portion;
a base portion protruding from the body portion in a second direction;
a protrusion protruding and extending from the base portion in the second direction; and
a second control hook protruding from the protrusion in a thickness direction, and
wherein the control printed circuit board is fixed on the body portion and the protrusion by the first control hook and the second control hook.

18. The display apparatus of claim 17, wherein the guide holder further includes:
a first seating portion extending from the base portion to one side in a first direction intersecting the second direction;
a first partition curved from the first seating portion and protruding in the thickness direction; and
a first source hook protruding from the body portion toward the first seating portion.

19. The display apparatus of claim 18, further comprising:
a flexible film connected to the display panel;
a source printed circuit board connected to the flexible film;
a connection member connected to the printed circuit board; and
a control printed circuit board connected to the connection member,
wherein the source printed circuit board is fixed on the first seating portion by the first partition and the first source hook.

20. The display apparatus of claim 17, wherein the body portion further includes a body protrusion protruding from the body portion in the thickness direction,
wherein the control printed circuit board defines a substrate hole passing therethrough in the thickness direction, and
wherein the body protrusion is inserted into the substrate hole.
